(19) United States
(12) Patent Application Publication
(10) Pub. No.: US 2009/0266589 A1
(43) Pub. Date: Oct. 29, 2009

(54) PROCESS FOR PRODUCING METAL WIRING BOARD

(75) Inventors: Hiroto Shimokawa, Ube-shi (JP); Nobu Iizumi, Ube-shi (JP); keita Bamba, Ichihara-shi (JP); Tadahiro Yokozawa, Ichihara-shi (JP)

Correspondence Address: KNOBBE MARTENS OLSON & BEAR LLP, 2040 MAIN STREET, FOURTEENTH FLOOR, IRVINE, CA, 92614, US

(73) Assignee: UBE INDUSTRIES, LTD., Ube-she (JP)

(21) Appl. No.: 12/090,245

(22) PCT Filed: Oct. 13, 2006
(86) PCT No.: PCT/JP2006/320510

§ 371 Date: Jan. 4, 2009

(30) Foreign Application Priority Data
Oct. 14, 2005 (JP) 2005-300995

(51) Int. Cl. H05K 1/09; H05K 3/06

(52) U.S. Cl. 174/256; 216/20

(57) ABSTRACT

Is disclosed a process for producing a metal wiring substrate comprising a heat resistant resin substrate and a metal wiring which is laminated on the substrate and in which a surface laminated with the substrate is surface-treated with at least one metal selected from Ni, Cr, Co, Zn, Sn and Mo or an alloy comprising at least one of these metals (hereafter, the metal used for the surface-treatment is referred to as a surface-treatment metal). This process comprises the steps of forming the metal wiring on the resin substrate, and washing at least a surface of the resin substrate with an etching solution capable of removing the surface-treatment metal to increase adhesion of the surface of the resin substrate. The produced metal wiring substrate has excellent adhesion with adhesives for affixing anisotropic conductive films and IC chips to films.

### TECHNICAL FIELD

The present invention relates to a process for producing a metal wiring heat resistant resin substrate having excellent adhesion with adhesives such as epoxy resin for affixing anisotropic conductive films (hereafter, ACF) and IC chips to films. Particularly, the present invention relates to the metal wiring heat resistant resin substrate usable for high-performance electronic devices, in particular flexible wiring substrates, built-up circuit substrates and IC carrier tapes suitable for reduction in size with high-density wirings.

### BACKGROUND ART

Conventionally, metal foil laminated heat resistant resin film, in which metal foil such as copper foil is laminated to heat resistant resin film such as polyimide film, have been used for high-performance electronic devices, in particular flexible wiring substrates and IC carrier tapes with high-density wirings and suitable for reduction in size and weight because of their excellent properties with thinness and lightness in weight.

When the process producing metal foil laminated heat resistant resin film is the metalizing-type production, it is known that forming copper layer is costly, thickening copper foil is difficult, adhesion of copper and heat resistant resin film is weak, and reliability of adhesion is low. Therefore, the metal foil laminate heat resistant resin films in which metal foil such as copper foil is laminated on resin film such as polyimide by lamination method are widely used.

Due to miniaturization of metal wirings, adhesives for affixing ACF and IC chips to film and improvement of its adhesion have been recently proposed. For improved heat resistant resin film, Patent document 1 discloses a copper-clad laminate using thermoplastic polyimide resin. It is a flexible metal foil laminated board in which heat-resistant bond-ply having the thermoplastic polyimide layer on at least one side face of heat-resistant base film and foil-layer metal are thermally laminated. The copper-clad laminate is characterized in that thermoplastic polyimide resin comprises 0 to 50% of DA3EG in diamine component and BPDA or ODPA or BTDA as acid main component, and has adhesion with ACF of 5 N/cm or more, no white turbidity in thermoplastic polyimide layer during the solder-dipping test at 260° C. for 10 sec after moisture absorbent at 40° C., 90RH % for 96 hours and no delamination between thermoplastic polyimide layer and metal foil. In addition, Patent document 2 discloses a flexible metal foil laminate in which heat-resistant Bond-Ply having a thermoplastic polyimide layer on at least one side face of heat-resistant base film and foil-layer metal are thermally laminated, wherein the thermoplastic polyimide resin has hydroxyl group or carboxyl group for 5 to 50% of diamine component and used as adhesive.

Furthermore, as improvement in adhesives for affixing resin film to copper foil, Patent document 3 discloses a thin tissue wiring board material with 100 μm or less in the total thickness of composite, comprising A: a viscoelastic resin composition and B: a conductor layer on one side or both sides of composite with polyimide film, in which the storage elastic modulus of the viscoelastic resin composition is 300 to 1,700 MPa at 20° C., the viscoelastic resin composition has 2 to 10 part of glycidyl acrylate in the polymer, epoxy number is 2 to 18, and acrylic polymer with 50,000 or more in weight-average molecular weight (Mw) is a necessary component.

For the purpose to improve surface roughness of resin film, Patent document 4 discloses a resin film having a surface shape characterized in that the value Ra1 of at least one side of the film measured on the basis of a cut-off value of 0.002 mm of arithmetic average roughness is 0.05 to 1 μm and a ratio Ra1/Ra2 of the value Ra1 and a value Ra2 measured on the basis of a cut-off value of 0.1 mm is 0.4 to 1.

Patent document 1: Japanese Laid-open Patent Publication No. 2002

Patent document 2: Japanese Laid-open Patent Publication No. H11

Patent document 3: Japanese Laid-open Patent Publication No. H11

Patent document 4: Japanese Laid-open Patent Publication No. 2004

### DISCLOSURE OF THE INVENTION

### Problems to be Solved by the Invention

However, when fine wiring is formed by etching metal foil, adhesion between heat resistant resin film surface in which metal foil is removed between wirings, and adhesives for affixing ACF and IC chips to film may be insufficient.

In view of these problems, an objective of the present invention is to provide a process for producing a metal wiring substrate, which can improve adhesion of the metal wiring substrate surface where wiring is formed by etching and removing metal foil such as copper foil from heat resistant resin substrate surface such as polyimide.

### Means for Solving the Problems

The present invention relates to the followings.

1. A process for producing a metal wiring substrate comprising a heat resistant resin substrate and a metal wiring which is laminated on the substrate and in which a surface laminated with the substrate is surface-treated with at least one metal selected from Ni, Cr, Co, Zn, Sn and Mo or an alloy comprising at least one of these metals (hereafter, the metal used for the surface-treatment is referred to as a surface-treatment metal), comprising the steps of:

forming the metal wiring on the resin substrate, and

washing at least a surface of the resin substrate with an etching solution capable of removing the surface-treatment metal to increase adhesion of the surface of the resin substrate.

2. The production process according to the above item 1, wherein the metal wiring substrate is used for an application in which an adhesive organic material layer is formed on at least a part of a bare face of the resin substrate on which the metal wiring is formed.
3. The production process according to the above item 2, wherein the adhesive organic material layer is a layer having at least one function selected from a conductive layer, an insulating layer, a protective layer, an adhesive layer, an encapsulating layer and a sealing layer.
4. The production process according to one of the above items 1 to 3, wherein the etching solution is capable of removing the surface-treatment metal at a faster rate than a rate for a material of the metal wiring.
5. The production process according to one of the above items 1 to 4, wherein at least one of a surface of the resin substrate and a surface of the metal wiring is treated with a silane coupling agent at a laminating face of the resin substrate and the metal wiring, and

wherein the washing step is carried out so that a surface silicon atomic concentration after the treatment becomes higher than that before the treatment.

6. The production process according to one of the above items 1 to 5, wherein the resin substrate is one in which a thermocompression-bondable polyimide layer is laminated on at least one side of a heat resistant polyimide layer, and the thermocompression-bondable polyimide layer is the laminating face with the metal wiring.
7. The production process according to one of the above items 1 to 6, wherein the etching solution is an acidic etching solution.
8. The production process according to one of the above items 1 to 6, wherein the etching solution is an etching agent for a Ni—Cr alloy. In this case, the surface-treatment metal is preferably at least one metal selected from Ni and Cr or is selected from alloy comprising at least one of these metals.
9. The production process according to one of the above items 1 to 8, wherein the step for forming the metal wiring, comprising the steps of preparing a laminate substrate in which a metal foil is laminated on at least one side of the resin substrate, and forming the metal wiring on the resin substrate by etching and pattering the metal foil.
10. The production process according to one of the above items 1 to 9, wherein the metal wiring is copper wiring.
11. The production process according to one of the above items 1 to 10, further comprising a step of plating a metal after the washing step.
12 The metal wiring substrate produced by the production process according to one of the above items 1 to 11, comprising the heat resistant resin substrate and the metal wiring which is laminated on the substrate and in which the surface laminated with the substrate is surface-treated with at least one metal selected from Ni, Cr, Co, Zn, Sn and Mo or an alloy comprising at least one of these metals (hereafter, the metal used for the surface-treatment is referred to as a surface-treatment metal).
13. The metal wiring substrate according to the above item 12, wherein the adhesive organic material layer is formed contacting the resin substrate face of the metal wiring substrate.
14. The metal wiring substrate according to the above item 13, wherein the adhesive organic material layer is a layer having at least one function selected from the protective layer, the adhesive layer, the encapsulating layer and the sealing layer.

The production process according to the present invention may preferably applied for producing the metal wiring substrate particularly having fine pattern not more than 80 μm pitch in terms of the pitch of metal wiring.

The substrate produced in accordance with the present invention may be preferably used as particularly flexible wiring circuit substrates, built-up circuit substrates and IC carrier tape substrates.

### EFFECT OF THE INVENTION

For the metal wiring substrate produced in accordance with the present invention, adhesion of the bare substrate surface between metal wirings is improved. When adhesive organic material layer is formed, adhesion of the layer and the substrate is excellent. Therefore, when the organic material layer functions as at least one layer selected from a conductive layer (including, for example, an anisotropic conductive layer), an insulating layer, a protective layer (including, for example, a solder resist layer), an adhesive layer, an encapsulating layer and a sealing layer, its reliability can be increased. For example, since adhesion of polyimide film face and adhesion such as epoxy resin and the like is excellent, reliability can be increased when ACF and IC chips are affixed to metal wiring polyimide film substrate.

This is because the polyimide substrate surface is bared in a suitable condition for adhesion by the washing step according to the present invention. In case that the polyimide film surface and/or metal wiring surface is treated with a silane coupling agent as shown in an embodiment according to the present invention, it is presumed that during the washing step the film does not receive such a damage that deteriorates the effect of the silane coupling treatment, and the substrate surface is bared in a condition so as to exert the effectiveness of the silane coupling treatment.

Moreover, even when at least a part of metal wiring is metal-plated such as tin-plated after washing step of the present invention, the surface adhesion is not deteriorated.

In the metal wiring substrate produced in accordance with the present invention, micro wiring not more than 40 μm in pitch or not more than 50 μm in pitch can be formed, and high-density flexible wiring substrates, built-up circuit substrates and IC carrier tapes can be obtained.

### BRIEF DESCRIPTION OF THE DRAWINGS

FIG. 1 is an image, obtained by a metallographic microscope, of the surface of the tin-plated copper-wiring polyimide film in the example 4 according the present invention.

FIG. 2 is an image, obtained by a metallographic microscope, of the surface of the tin-plated copper-wiring polyimide film in the comparative example 4 according the present invention.

### EXPLANATION OF THE REFERENCES

1: Tin-plated copper wiring
2: Polyimide film surface where copper foil is removed
3: Anomalous deposition site of tin-plating

### BEST MODE FOR CARRYING OUT THE INVENTION

In the present invention, the metal wiring on the substrate is preferably formed by etching and patterning the metal foil laminated on the heat resistant resin substrate.

The metal foil is, on at least its one side, surface-treated such as roughening treatment, anti-corrosion treatment, heat-resistant treatment, chemical resistant treatment and so on with at least one metal selected from the surface-treatment metal (i.e., Ni, Cr, Co, Zn, Sn and Mo or an alloy comprising at least one of these metals). Therefore, these metals exist on the metal foil surface. One further surface-treated with a silane coupling agent may also be used preferably The face to be laminated with the heat resistant resin substrate is the face surface-treated. In particular, if the surface of the heat resistant resin substrate is not treated with the silane coupling agent, the surface of the metal foil is extremely preferably treated with the silane coupling agent. The metal foil may be formed on the both sides of the heat resistant resin substrate (for example, a film), and the metal wiring may be formed on the both sides.

Here, the examples of the silane coupling agent include epoxy-based silane coupling agent, amino-based silane coupling agent, mercapto-based silane coupling agent. Specifically, the examples, as typically similar to coupling agents used for glass-cloth of prepreg for a print wiring board, include vinyltrimethoxysilane, vinyltris(2-methoxyethoxy)silane, vinylphenyltrimethoxysilane, γ-methacryloxypropyltrim ethoxysilane, γ-glycidoxypropyltrimethoxysilane, 4-glycidylbutyltrinethoxysilane, γ-aminopropyltriethoxysilane, N-β-(aminoethyl)-γ-aminopropyltrimethoxysilane, N-3-(4-(3-aminopropoxy) butoxy)propyl-3-aminopropyltrimethoxysilane, imidazolesilane, triazinesilane, γ-mercaptopropyltrimethoxysilane. In addition to silane coupling agent, the present invention may be also effective for one treated with titanate-based and zirconate-based coupling agents.

The metal foil is not limited in particular, but preferably used are copper and copper alloy such as electrolytic copper foil, rolled copper foil and the like, aluminum and aluminum alloy, stainless steel and its alloy, nickel and nickel alloy (including 42 alloy) and the like. These are not more than 100 μm, preferably 0.1 to 100 μm, particularly 1 to 100 μm in thickness.

The surface roughness of the metal foil laminated to the heat resistant resin substrate is not limited in particular, but smooth surface may be used so that Ra of the roughened face of the metal foil, side affixed to the heat resistant resin substrate, is preferably 2.0 μm or less, furthermore preferably 1.5 μm or less, more preferably 1.0 μm or less, particularly preferably 0.27 μm or less.

When thin metal foil (for example, 0.1 to 8 μm in thickness) is used, it may be laminated with a protective foil (for example, a carrier foil) having a function to reinforce and protect the metal foil. The materials of the protective foil (the carrier foil) are not limited in particular and may be used as long as they can function so as to be stuck to the metal foil such as extremely-thin copper foil, reinforce and protect the metal foil such as the extremely-thin copper foil and for example, may be used aluminum foil, copper foil, resin foil with metal-coated surface and so on. The thickness of the protective foil (the carrier foil) is not limited in particular, but may be used as long as they can reinforce thin metal foil, and generally may be preferably used with 10 to 200 μm in thickness, furthermore 12 to 100 μm in thickness, particularly 15 to 75 μm in thickness. The protective foil (the carrier foil) may be used so as to be planarly stuck to extremely-thin metal foil such as extremely-thin copper foil.

The protective foil (the carrier foil) that can be used is those travel through a series of manufacturing steps, and keep juncture with the metal foil layer at least until completion of producing the metal laminated heat resistant resin substrate, and facilitate handling. The protective foil (the carrier foil), which may be used, is removed by peeling after laminating the protective foil (the carrier foil) to the heat resistant resin substrate, or may be removed by etching after laminating the protective foil (the carrier foil) to the heat resistant resin substrate. In the case of the carrier-accompanied electrolytic copper foil, since copper components are electrodeposited on the carrier foil surface to form electrolytic copper foil, carrier foil needs to have conductivity at least.

As the carrier-accompanied extremely-thin copper foil, examples include Nippon Denkai's product (YSNAP-3B: carrier thickness 18 μm/thin copper foil thickness: 3 μm), extremely-thin copper foil made by Olin Corporation (XTF: copper foil thickness 5 μm/carrier thickness 35 μm, copper foil thickness 3 μm/carrier thickness 35 μm etc), extremely-thin copper foil made by Furukawa Electric (F-CP: thickness 5 μm/35 μm, thickness 3 μm/35 μm, each extremely-thin copper foil/carrier copper foil).

The properties of the heat resistant resin substrate is not limited in particular, but preferably the substrate has to be laminated with the metal foil without any problem, has to be manufactured and handled easily, has to allow etching of metal foil such as copper foil thereon and has to have excellent heat resistance and electrical insulation. Further, the substrate can sufficiently support the metal foil if needed, and is not seriously damaged by developing liquid or stripping liquid to remove photoresist layer to be used when metal wiring is formed if needed.

Particularly for properties of the heat resistant resin substrate, preferably its heat shrinkage factor is not more than 0.05%, its linear expansion coefficient (50 to 200° C.) is close to a linear expansion coefficient of metal foil such as copper foil to be laminated to the heat resistant resin substrate, and the linear expansion coefficient (50 to 200° C.) of the heat resistant resin substrate is preferably 0.5×10⁻⁵ to 2.8×10⁻⁵ cm/cm/° C. when copper foil is used as metal foil.

The examples of the heat resistant resin substrate include polyimide, polyamide, aramid, liquid crystal polymer, polyethersulfone, polysulfone, polyphenylenesulfide, polyphenyleneoxide, a polyetherketone, polyetheretherketone, polybenzazol, BT (bismaleimide-triazin) resin, epoxy resin, thermosetting polyimide and the like. A substrate of these resins in film-form, sheet-form and board-form may be used.

Particularly for the heat resistant resin substrate, polyimide may be preferably used because it has excellent heat resistance and flame retardancy, high stiffness and excellent electrical insulation.

As the heat resistant resin substrate, there may be exemplified, but not limited to, commercial polyimide films comprising as main components an acid component selected from biphenyltetracarboxylic acid skeleton structure and pyromellitic acid skeleton structure, and diamine component selected from phenylenediamine skeleton structure, diaminodiphenylether skeleton structure and biphenyl skeleton, such as “Upilex (S, R)” (brand name) made by Ube Industries, “Kapton (H, EN, K)” (brand name) made by DuPont-TORAY, “Apical (AH, NPI, HP)” (brand name) made by Kanegafuchi Chemical Industry, “Espanex (S, M)” (brand name) made by Nippon Steel Chemical, “Mictron” (brand name) made by TORAY and the like, and commercial liquid crystal polymers such as “Vecstar” (brand name) made by Kuraray Corporation, “Espanex (L)” (brand name) made by Nippon Steel Chemical and the like.

The heat resistant resin substrate may also be in the forms molded with fillers such as inorganic fillers and organic fillers, and fiber materials such as glass fibers, aramid fibers, polyimide fibers, where the fillers may be in a form of short fibers, woven, knitted, raftered or nonwoven.

For the heat resistant resin substrate, it may be used in the form of mono-layer, multi-layer film laminated with two or more layers, a sheet and board.

The thickness of the heat resistant resin substrate is not limited in particular, but preferably is in the range that laminating with the metal foil can be done without any problem, manufacturing and handling can be done, and the metal foil can be sufficiently supported. Preferably it may be in the range 1 to 500 μm, more preferably 2 to 300 μm, furthermore preferably 5 to 200 μm, more preferably 7 to 175 μm, particularly preferably 8 to 100 μm.

The heat resistant resin substrate may be surface-treated such as corona discharge treatment, plasma treatment, chemical roughening treatment, physical roughening treatment and so on at least on one side of the substrate. Particularly, surface-treated substrate with a silane coupling agent is also preferable. In particular, if the surface of the metal foil is not treated with silane coupling agent, the surface of the heat resistant resin substrate is preferably surface-treated, in particular, extremely preferably treated with the silane coupling agent.

As the surface treatment agent to be used for the surface treatment, silane coupling agents such as amino-based and epoxy-based type, and titanate-based surface treatment agents may be exemplified. The examples of the amino-based silane coupling include γ-aminopropyl-triethoxysilane, N-β-(aminoethyl)-γ-aminopropyl triethoxysilane, N-(aminocarbonyl)-γ-aminopropyltriethoxysilane, N-[β-(phenylamino)-ethyl]-γ-aminopropyltriethoxysilane, N-phenyl-γ-aminopropyltriethoxysilane, γ-phenylaminopropyltrimethoxysilane; the examples of the epoxy-bases silane coupling agents include β-(3,4-epoxycyclohexyl)ethyltrimethoxysilane, γ-glycidoxypropyltrimethoxysilane, and the examples of the titanate-based surface treatment agents include isopropyltricumylphenyl titanate, dicumylphenyloxyacetate titanate.

For the surface treatment agent, silane coupling agents such as amino-based and epoxy-based are preferable.

The term surface treated include the case that the surface treatment agent is contained as it is, and the case that the surface of the heat resistant resin substrate surface causes chemical change, in case of polyimide film, by heating at 320 to 550° C. in polyimide or polyimide precursors or organic solutions of these.

If the handling of the heat resistant resin substrate is difficult due to low stiffness of the substrate, the substrate may be used with a removable and stiff film or substrate affixed to the back side. These are removable during a post-step.

As the heat resistant resin substrates, polyimide films having excellent heat resistance and electrical insulation may be preferably used.

The polyimide film used herein preferably has heat shrinkage factor of not more than 0.05% and linear expansion coefficient (50 to 200° C.) close to a linear expansion coefficient of metal foil such as copper foil to be laminated to the heat resistant resin substrate. The linear expansion coefficient (50 to 200° C.) of the heat resistant resin substrate is preferably 0.5×10⁻⁵ to 2.8×10⁻⁵ cm/cm/° C. when copper foil is used as metal foil.

As the polyimide film, mono-layer polyimide film or multi-layer polyimide film laminated with two or more layers of polyimide is used. Kind of polyimide is not particularly limited.

The polyimide film may be prepared by a known method, and for example, for mono-layer polyimide film, the following method may be utilized:

(1) The method of flow-casting or applying a solution of a poly(amic acid) as a polyimide precursor on a suport, and imidizing it,

(2) The method of flow-casting or applying a polyimide solution on a suport, and then, if necessary, heating it.

For two or more layers polyimide film, the following method may be utilized:

(3) The method of flow-casting or applying a solution of a poly(amic acid) as a polyimide precursor on a support, and furthermore flow-casting or applying successively a solution of a poly(amic acid) as a polyimide precursor for the second or later layer on the upper face of the previous poly(amic acid) layer flow-casted or applied on the support, and imidizing them,

(4) The method of simultaneously flow-casting or applying solutions of a poly(amic acid) for two or more layers as a polyimide precursor on a support, and imidizing them,

(5) The method of flow-casting or applying a polyimide solution on a support, and furthermore successively flow-casting or applying a polyimide solution for the second or later layer on the upper face of the previous polyimide layer flow-casted or applied on the support, and, if necessary, heating them,

(6) The method of simultaneously flow-casting or applying polyimide solutions for two or more layers on a support, and, if necessary, heating them,

(7) The method of laminating two or more polyimide films obtained by the above methods (1) to (6) directly or through adhesive.

The heat resistant resin substrate, which may be used herein, is a polyimide film having thermocompression-bondable property with two or more layers of thermocompression-bondable polyimide (S2) layer(s) on at least one sides of a heat-resistant polyimide layer (S1). As an example of layer constitution of the multi-layers polyimide film, S2/S1, S2/S1/S2, S2/S1, S2/S1, S2/S1/S2/1S1/S2 and so on are exemplified.

In the polyimide film having thermocompression-bondable property, thicknesses of the heat-resistant polyimide layer (S1) and the thermocompression-bondable polyimide (S2) may be appropriately selected, and the thickness of the thermocompression-bondable polyimide (S2) of the top-surface layer of the thermocompression-bondable polyimide film is within a range of 0.5 to 10 μm, preferably 1 to 7 μm, more preferably 2 to 5 μm. Curling can be reduced by forming the thermocompression-bondable polyimide layers (S2) having almost the same thickness on the both sides of the heat-resistant polyimide layer (S1).

In the polyimide film having thermocompression-bondable property, heat-resistant polyimide used for the heat-resistant polyimide layer (S1 layer), may be selected from those having at least one of the following properties, or those having at least two of the following properties {i.e. the combination of 1) and 2), 1) and 3) or 2) and 3)}, particularly from those having all of the following properties.

1) In the case of polyimide film alone, a glass transition temperature is 300° C. or higher, preferably 330° C. or higher, and further preferably, a glass transition temperature is undetectable.

2) In the case of polyimide film alone, a linear expansion coefficient (50 to 200° C.) (MD) is close to a thermal expansion coefficient of a metal foil such as a copper foil laminated on the polyimide film, and when using a copper foil as a metal foil, a thermal expansion coefficient of the polyimide film is preferably 5×10⁻⁶ to 28×10⁻⁶ cm/cm/° C., more preferably 9×10⁻⁶ to 200×10⁻⁶ cm/cm/° C., further preferably 12×10⁻⁶ to 18×10⁻⁶ cm/cm/° C.

3) In the case of polyimide film alone, a tensile modulus (MD, ASTM-D882) is 300 kg/mm² or more, preferably 500 kg/mm² or more, further preferably 700 kg/mm² or more.

4) Preferably its heat shrinkage factor is not more than 0.05%.

As the heat-resistant polyimide layer (S1), such polyimide may be used that prepared from the combination of acid component predominantly comprising 3,3′,4,4′-biphenyltetracarboxylic dianhydride (s-B PDA), pyromellitic dianhydride (MDA) and 3,3′,4,4′-benzophenonetetracarboxylic dianhydride (BTDA), and a diamine component predominantly comprising p-phenylenediamine (PPD) and 4,4′-diaminodiphenyl ether (DADE). The preferable examples are listed as follows.

(1) The polyimide produced from 3,3′,4,4′-biphenyltetracarboxylic dianhydride (s-BPDA) and p-phenylenediamine (PPD) and optionally 4,4′-diaminodiphenyl ether (DADE). In this case, a ratio of PPD/DADE (molar ratio) is preferably 100/0 to 85/15.

(2) The polyimide produced from 3,3′,4,4′-biphenyltetracarboxylic dianhydride and pyromellitic dianhydride and p-phenylenediamine and 4,4′-diaminodiphenyl ether. In this case, a ratio of BPDA/PMDA is preferably 15/85 to 85115 and a ratio of PPD/DADE is preferably 90/10 to 10/90.

(3) The polyimide produced from pyromellitic dianhydride, p-phenylenediamine and 4,4′-diaminodiphenyl ether. In this case, a ratio of DADEIPPD is preferably 90/10 to 10/90.

(4) The polyimide produced from 3,3′,4,4′-benzophenonetetracarboxylic dianhydride (BTDA) and pyromellitic acid dianhydride and 4,4′-diaminodiphenyl ether. In this case, a ratio of BTDA/PMDA in acid dianhydrides is preferably 20/80 to 90/10 and a ratio of PPD/DADE in diamines is preferably 30/70 to 90/10.

The synthesis of the heat-resistant polyimide for the heat-resistant polyimide layer (S1 layer) is accomplished by any method such as random polymerization, or block polymerization or the method including combining solutions of two kinds of poly(amic acid) synthesized beforehand, and mixing under the reaction condition to give a uniform solution.

In the synthesis of the heat-resistant polyimide, by using the aforementioned each component, the almost-equimolar amounts of diamine components and dianhydrides are reacted in an organic solvent to give a poly(amic acid) solution (it may be partially imidized as long as uniform solution condition is kept).

Other tetracarboxylic dianhydrides or diamines, of which the kind and the amount are chosen so as not to degrade the properties of the heat-resistant polyimide, may be used.

On the other hand, the thermocompression-bondable polyimide for the thermocompression-bondable polyimide layer (S2) is a polyimide 1) which has thermocompression-bondable property to metal foil, preferably is thermocompression-bondable by laminating with metal foil at a temperature not lower than a glass transition temperature of the thermocompression-bondable polyimide (S2) and not higher than 400° C.

Furthermore, the thermocompression-bondable polyimide of the thermocompression-bondable polyimide layer (S2) preferably has at least one of the following properties.

2) A thermocompression-bondable polyimide (S2) has a peel strength between a metal foil and the polyimide (S2) of 0.7 N/mm or more, and the retention of a peel strength after heat treatment at 150° C. for 168 hours is 90% or more, further 95% or more, particularly 100% or more.

3) Its glass transition temperature is from 130 to 330° C.

4) Its tensile modulus is 100 to 700 Kg/mm².

5) Its linear expansion coefficient (50 to 200° C.) (MD) is 13 to 30×10⁻⁶ cm/cm/° C.

The thermocompression-bondable polyimide of the thermocompression-bondable polyimide layer (S2) may be selected from known thermoplastic polyimides. For example, there may be used a polyimide prepared from an acid component comprising at least one selected from acid dianhydrides such as 2,3,3′,4′-biphenyltetracarboxylic dianhydride (a-BPDA), 3,3′,4,4′-biphenyltetracarboxylic dianhydride (s-BPDA), pyromellitic dianhydride (PMDA), 3,3′,4,4′-benzophenonetetracarboxylic dianhydride (BTDA), 3,3′,4,4′-diphenylsulfonetetracarboxylic dianhydride, 4,4′-oxydiphthalic dianhydride (ODPA), p-phenylenbis(trimellitic monoester anhydride), 3,3′,4, 4′-ethyleneglycoldibenzoatetetracarboxylic dianhydride, preferably comprising them as a main component, and a diamine component having at least three benzene rings in its main chain, comprising at least one selected from diamines such as 1,4-bis(4-aminophenoxy) benzene, 1,3-bis(4-aminophenoxy) benzene, 1,3-bis(3-aminophenoxy) benzene, 2,2-bis[4-(4-aminophenoxy) phenyl] propane, 2,2-bis[4-(3-aminophenoxy) phenyl] propane, bis[4-(4-aminophenoxy) phenyl] sulfone, bis[4-(3-aminophenoxy) phenyl] sulfone, preferably comprising them as a main component, and further comprising a diamine component having one or two benzene rings in its main chain if needed.

The thermocompression-bondable polyimide preferably used herein is polyimide prepared from preferably an acid component selected from 2,3,3′,4′-biphenyltetracarboxylic acid dianhydride (a-BPDA), 3,3′,4,4′-biphenyltetracarboxylic acid dianhydride (s-B PDA), pyromellitic acid dianhydride (PMDA) and 3,3′,4,4′-benzophenonetetracarboxylic acid dianhydride (BTDA), and a diamine component selected from 1,4-bis(4-aminophenoxy) benzene, 1,3-bis(4-aminophenoxy) benzene, 1,3-bis(3-aminophenoxy) benzene and 2,2-bis[4-(4-aminophenoxy) phenyl] propane. If needed, a diamine component having one or two benzene rings in its main chain, and diamine and acid components other than described above may be comprised.

Particularly preferred is those prepared from a diamine component comprising 80 mol % or more of 1,3-bis(4-aminophenoxy) benzene (hereafter, may be referred as TPE3R) and 3,3′,4,4′-biphenyltetracarboxylic dianhydride and 2,3,3′,4′-biphenyltetracarboxylic acid dianhydride (hereafter, may be referred as a-BPDA). In this case, s-BPDA/a-BPDA is preferably 100/0 to 5/95, and may be replaced with other tetracarboxylic acid dianhydrides for example, 2,2-bis(3,4-dicarboxyphenly)propane acid dianhydride, 2,3,6,7 naphtarentetracarboxylic dianhydride and so on, in such an amount that the properties of the thermocompression-bondable polyimide is degraded.

The thermocompression-bondable polyimide may be prepared by a method in which each the aforementioned component and further other tetracarboxylic acid dianhydrides and other diamines are reacted in a organic solvent at a temperature not higher than 100° C., particularly 20 to 60° C. to give a poly(amic acid) solution, and then using this poly(amic acid) solution as a dope liquid, the film of the dope liquid is formed, and its solvent is evaporated from the film and at the same time poly(amic acid) is imide-cyclized.

Alternatively, the organic solvent solution of the thermocompression-bondable polyimide may be obtained by heating the poly(amic acid) solution prepared as above at 150 to 250° C., or adding imidization agent at 150° C. or lower, particularly reacting at 15 to 50° C., and followed by evaporating solvent after imidization, or followed by precipitation in poor solvent to give powder and dissolving the powder in organic solution.

To obtain the thermocompression-bondable polyimide, the ratio of amount of diamines (as a mole of amino groups) to the total mole of acid anhydrides (as the total mole of acid anhydride groups of tetra acid dianhydrides and dicarboxylic acid anhydrides) is preferably 0.95 to 1.0, particularly 0.98 to 1.0, particularly among them 0.99 to 1.0. When dicarboxylic acid anhydrides are used, their amount as the ratio of tetra acid dianhydrides to the mole of acid anhydride groups is 0.55 or lower so that individual components can be reacted.

When molecular weight of the poly(amic acid) obtained is low in the production of the thermocompression-bondable polyimide, the adhesion strength to the metal foil in the laminate may be lowered.

In addition, for the purpose to restrict gelation of the poly(amic acid), phosphorus-base stabilizer, for example, triphenyl phosphite, triphenyl phosphate and so on may be added within a range of 0.01 to 1% of solids (polymer) during polymerization of the poly(amic acid).

In addition, for the purpose to promote imidization, a basic organic compound may be added to the dope liquid. For example, imidazole, 2-imidazole, 1,2-dimethylimidazole, 2-phenylimidazole, benzimidazole, isoquinoline, substituted-pyridine and so on may be used in a proportion of 0.05 to 10 wt %, particularly 0.1 to 2 wt % of the poly(amic acid). Since these can form polyimide film at a relatively low temperature, these may be used to avoid insufficient imidization.

In addition, for the purpose to stabilize the adhesion strength, organic aluminum compounds, inorganic aluminum compounds or organic tin compounds may be added to the poly(amic acid) solution for the polyimide. For example, aluminum hydroxide, aluminum triacetylacetonate and so on may be added at 1 ppm or more, particularly 1 to 1000 ppm as aluminum metal to the poly(amic acid).

As for the organic solvent used for producing the poly(amic acid) from the acid component and diamine component, for both of the heat-resistant polyimide and the thermocompression-bondable polyimide, are exemplified N-methyl-2-pyrrolidone, N, N-dimethylformamide, N, N-dimethylacetamide, N, N-diethylacetamide, dimethylsulfoxide, hexamethylphosphoramide, N-methylcaprolactam, cresols. These organic solvents may be used alone or more than two kinds together.

For both of the heat-resistant polyimide and the thermocompression-bondable polyimide, in order to block their terminal, dicarboxylic anhydrides may be used, such as phthalic anhydride and its substitution product, hexahydrophthalic anhydride and its substitution product, succinic anhydride and its substitution product and so on, particularly phthalic anhydride.

The polyimide film having thermocompression-bondable property may be obtained preferably by a method (i) or (ii), i.e.

(i) By the coextrusion-flow-casting film formation method (also being simply referred to as multi-layers extrusion), the dope liquid of the heat-resistant polyimide (S1) and the dope liquid of the thermocompression-bondable polyimide (S2) is laminated, dried and imidized to give multi-layers polyimide film, or
(ii) the dope liquid of the heat-resistant polyimide (S1) is flow-cast on a support, and dried to give self-supporting film (gel film), and next, on one side or both sides thereof, the dope liquid of the thermocompression-bondable polyimide (S2) is applied, and dried and imidized to give the multi-layers polyimide film.

For the coextrusion method, may be used the method described in the Japanese Laid-open Patent Publication No. H03-180343 (Japanese Kokoku Patent Publication No. H07-102661).

An embodiment of the production of three-layer polyimide film having thermocompression-bondable properties on both sides is indicated. The poly(amic acid) solution of the polyimide (S1) and the poly(amic acid) of polyimide (S2) are supplied to a three-layer extrusion molding die by three-layer coextrusion method so that the thickness of the heat-resistant polyimide layer (S1 layer) is 4 to 45 μm and the thickness of the thermocompression-bondable polyimide layer (S2 layer) on both sides is 3 to 10 μm in the total, and cast on a support and this is flow-cast and applied on a smooth support surface such as a stainless mirror surface and a stainless belt surface, and at 100 to 200° C. the polyimide film A as a self-supporting film is obtained in a semi-cured state or a dried state before the semi-curing.

For the polyimide film A as a self-supporting film, if a flow-casted film is treated at a temperature higher than 200° C., some defects tend to occur such as decrease in adhesiveness during preparation of the polyimide film having thermocompression-bondable property. This semi-cured state or the state before the semi-curing means a self-supporting state by heating and/or chemical imidization.

The polyimide film A as a self-supporting film obtained is heated at a temperature not lower than the glass transition temperature of polyimide (S2) and not higher than degradation-occurring temperature, preferably a temperature from 250 to 420° C. (surface temperature measured by a surface thermometer) (preferably heating at this temperature for 0.1 to 60 min.), and dried and imidized. Thus, the polyimide film having the thermocompression-bondable polyimide layer (S2 layer) on both sides of the heat-resistant polyimide layer (S1 layer) is produced.

In the polyimide film A as a self-supporting film obtained, solvent and generated water remains preferably at about 25 to 60 mass %, particularly preferably 30 to 50 mass %. The self-supporting film is preferably heated-up for relatively short period when it is heated-up to a drying temperature, for example, heating rate is not lower than 10° C./min preferably. When drying, by increasing tension applied for the self-supporting film, the linear expansion coefficient of polyimide film A finally obtained may be reduced.

Then, following the above-mentioned drying step, the self-supporting film is continuously or intermittently dried and heat-treated, in a condition in which a pair of side edge of the self-supporting film is fixed by a fixing equipment at least mobile continuously or intermittently together with the self-supporting film, at a high temperature higher than the drying temperature, preferably within a range from 200 to 550° C., particularly preferably within a range from 300 to 500° C., and preferably for 1 to 100 min., particularly 1 to 10 min. The polyimide film having thermocompression-bondable property on both sides may be formed by sufficiently removing solvent etc from the self-supporting film and at the same time sufficiently imidizing the polymer consisting of the film so that the contents of volatile components consisted of organic solvents and generated water is not more than 1 wt %.

The fixing equipment of the self-supporting film preferably used herein is equipped with a pair of belt or chain having many pins or holders at even intervals, along longitudinal both side of the solidified film supplied continuously or intermittently and is able to fix the film while the pair of belt or chain is continuously or intermittently moved with movement of the film. In addition, the fixing equipment of the above solidified film may be able to extend or shrink the film under heat treatment with suitable extension ratio or shrinkage ratio across-the-width or longitudinal (particularly preferably about 0.5 to 5% of extension or shrinkage ratio).

The polyimide film having thermocompression-bondable property on both sides having particularly excellent dimension stability may be obtained by heat-treating again the polyimide film having thermocompression-bondable property on both sides under low or no tension preferably not higher than 4N, particularly preferably not higher than 3N at a temperature of 100 to 400° C., and preferably for 0.1 to 30 min. In addition, thus produced lengthy polyimide film having thermocompression-bondable property on both sides may be rewound in a roll form by an appropriate known method.

In case that the polyimide film surface is treated with the silane coupling agent, the treatment is preferably carried out during the production step of the polyimide film. For example, the silane coupling agent in a solvent is preferably applied on the film in the state of the above-mentioned polyimide film A.

The metal laminated heat resistant resin substrates are those in which the surface-treated face of the metal foil is laminated with one side or both sides of the heat resistant resin substrate, and they are not limited by their production method.

For the metal laminated heat resistant resin substrate, may be used those in which

1) the surface-treated face of the metal foil is laminated with one side or both sides of the heat resistant resin substrate directly or through an adhesive,

2) the surface-treated face of the metal foil is laminated by heat with one side or both sides of the heat resistant resin substrate directly or through an adhesive,

3) the surface-treated face of the metal foil is laminated by pressure with one side or both sides of the heat resistant resin substrate directly or through an adhesive, or

4) the surface-treated face of the metal foil is laminated by heat and pressure with one side or both sides of the heat resistant resin substrate directly or through an adhesive.

Particularly, if the compression bonding of the substrate surface and the metal foil of the heat resistant resin substrate is weak even conducting by heat, pressure, or heat and pressure, it is preferable to laminate with an adhesive.

The adhesive may be applied by a generally-employed method such as a roll coater, a slit coater and a comma coater.

When adhesive layer-accompanied metal foil and heat resistant resin substrate, or metal foil and adhesive layer-accompanied heat resistant resin substrate are laminated, a heating machine, a compression machine or a thermocompression machine may be used, and preferably a heating or compression condition is appropriately selected depending on materials to be used. Although the production process is not particularly limited as long as continuous or batch laminating is employable, it is preferably carried out continuously by using a roll laminating or a double-belt press and the like.

As the metal laminated heat resistant resin substrate, also used is that in which the surface-treated face of metal foil is laminated through adhesive on at least one side of the above-described heat-resistant polyimide (S1).

In the metal laminated heat resistant resin substrate, when the heat-resistant polyimide (S1) and the metal foil are laminated through adhesive, the adhesive may be thermosetting or thermoplastic. The examples of thermosetting adhesive include epoxy resin, NBR-phenol-based resin, phenol-butyral-based resin, epoxy-NBR-based resin, epoxy-phenol-based resin, epoxy-nylon-based resin, epoxy-polyester-based resin, epoxy-acryl-based resin, acryl-based resin, polyamide-epoxy-phenol-based resin, polyimide-based resin, polyimidesiloxane-epoxy resin, and the examples of thermoplastic adhesive include polyamide-based resin, polyester-based resin, polyimide-based adhesive, polyimidesiloxane-based adhesive. In particular, polyimide adhesive, polyimidesiloxane-epoxy adhesive, epoxy resin adhesive may be preferably used.

The metal foil laminate heat resistant resin substrate may be preferably produced, using the above-mentioned polyimide film having the thermocompression-bondable polyimide layer (S2) on both sides or one side, by laminating the thermocompression-bondable polyimide layer (S2) and the treated-surface of the metal foil.

As an embodiment of the production method of the metal foil laminate heat resistant resin substrate in which the metal foil is laminated on both sides of polyimide film having thermocompression-bondable property, the following methods are exemplified.

1) Lengthy metal foil, lengthy polyimide film having thermocompression-bondable property and lengthy metal foil are piled in three layers in this order, and they are supplied to a thermocompression-bonding machine. In this process, they are preferable pre-heated at about 150 to 250° C., particularly at a temperature higher than 150° C. and 250° C. ° C. or lower for about 2 to 120 sec in line immediately before introducing in the machine by preferably using a pre-heater such as a hot-air blower or an infrared beating machine.

2) By using a pair of compression-bonding rolls or a double-belt press, the three-ply of metal foil/polyimide/metal foil is thermally bonded under pressure, wherein a temperature in a heating and compression-bonding zone of the pair of the compression-bonding rolls or the double-belt press is within a range of higher by 20° C. or more than a glass transition temperature of polyimide (S2) and below 400° C., particularly higher by 30° C. or more than the glass transition temperature and below 400° C.

3) In particularly the case of a double-belt press, the laminate is successively cooled while being pressed in a cooling zone to a temperature lower by 20° C. or more, particularly by 30° C. or more than the glass transition temperature of the polyimide (S2) to complete the lamination, and rewinded in a roll form. Thus, the roll-form both sides metal foil laminated polyimide film can be produced.

The metal foil laminate heat resistant resin substrate may be produced, using the above-described polyimide film having thermocompression-bondable property on both sides, by laminating the treated-surface of the metal foil to one side of the polyimide Film having thermocompression-bondable property.

As an embodiment of the production method of the one side metal foil laminate heat resistant resin substrate, the following methods are exemplified.

1) Lengthy metal foil, lengthy polyimide film having thermocompression-bondable property and a non-thermocompression-bondable lengthy film (Upilex made by Ube Industries, Kapton made by DuPont-TORAY etc) are piled in three layers in this order, and they are supplied to a thermocompression-bonding machine. In this process, they are preferable pre-heated at about 150 to 250° C., particularly at a temperature higher than 150° C. and 250° C. or lower for about 2 to 120 sec in line immediately before introducing in the machine by preferably using a pre-heater such as a hot-air blower or an infrared heating machine.

2) By using a pair of compression-bonding rolls or a double-belt press, the three-ply of metal foil/polyimide/polyimide is thermally bonded under pressure, wherein a temperature in a heating and compression-bonding zone of the pair of the compression-bonding rolls or the double-belt press is within a range of higher by 20° C. or more than a glass transition temperature of polyimide (S2) and below 400° C., particularly higher by 30° C. or more than the glass transition temperature and below 400° C.

3) In particularly the case of a double-belt press, the laminate is successively cooled while being pressed in a cooling zone to a temperature lower by 20° C. or more, particularly by 30° C. or more than the glass transition temperature of the polyimide (S2) to complete the lamination, and rewinded in a roll form. Thus, the roll-form one side metal foil laminated polyimide film can be produced.

In this production method, the pre-heating of the polyimide film before thermocompression-bonding prevents the occurrence of defective appearance by foaming in the laminate after thermocompression-bonding, and prevent the foaming when soaked in a solder bath during formation of electronic circuits, both due to moisture contained in the polyimide, and hence decreasing in production yield is prevented. Alternatively, a method in which the entire of a thermocompression-bonding machine is set in a furnace is conceivable; however, the method is substantially restricted to a compact thermocompression-bonding machine, and it is impractical because of restriction to the shape of the both sides metal foil laminated polyimide film. Even the pre-heat treatment out of line is performed, since the film re-absorb moisture until lamination, it is difficult to avoid the above-described defective appearance and decrease in solder heat resistance.

A double-belt press can perform heating up to high temperature and cooling clown under pressure, and a hydrostatic type using heat carrier is preferable.

In the production of both sides metal foil laminated polyimide film, a drawing rate is preferably 1 m/min or more by thermocompression bonding and cooling under pressure using a double-belt press and laminating the polyimide film having thermocompression-bondable on both sides and the metal foil. Thus-obtained both sides metal foil laminated polyimide film continuously long and have a width of about 400 mm or more, particularly about 500 mm or more, and high adhesive strength (the peel strength of the metal foil and the polyimide layer is 0.7 N/mm or more, and the retention rate of the peel strength is 90% or more after heating treatment at 150° C. and for 168 hours), and further has good appearance so that substantially no wrinkles are observed.

In order to mass-produce the both sides metal foil laminated polyimide film with good product appearance, while one or more combinations of the thermocompression-bondable polyimide film and the metal foil being supplied, protectors are placed between top-surface layer at both sides and the belt (i.e., two sheets of protector), and these together are preferably stuck and laminated by thermocompression bonding and cooling under pressure. For the protector, its material is particularly not limited for use as long as it is non-thermocompression bondable and have a good surface smoothness, and the preferred examples thereof include metal foil, particularly copper foil, stainless foil, aluminum foil, and high heat resistant polyimide film (Upilex made by Ube Industries, Kapton H made by DuPont-TORAY) and the like having about 5 to 125 μm in thickness.

As described above, the metal laminated heat resistant resin substrate in which the metal foil is laminated on at least one side of the heat resistant resin substrate is prepared. In the first step of the present invention, metal wiring is formed on the heat resistant resin substrate. For the formation of the metal wiring, wiring pattern is formed by partially removing the metal foil laminated with the heat resistant resin substrate by etching. A known method as etching method may be used, for example, using etching solution, using laser and the like. In the present invention, wet etching using etching solution is particularly preferred.

The metal wiring substrate preferably has metal wirings not more than 80 μm in pitch, not more than 50 μm in pitch, not more than 40 μm in pitch, not more than 30 μm in pitch, not more than 20 μm in pitch, or not more than 15 μm in pitch.

The specific method to produce the metal wiring substrate from the metal laminated heat resistant resin substrate (until the formation of a wiring pattern) is explained below. For the production methods explained in the formation methods 1 and 2 of a wiring pattern, particularly the present invention is preferably applied. When the metal foil is copper foil, relatively thick cooper foil is preferable, and its thickness is 3 μm or more, preferably 6 μm or more, for example, up to 300 μm, preferably up to 100 μm.

Formation method 1 of a wiring pattern:

1) Photoresist layer is formed by applying or affixing a film on the metal surface of the metal laminated heat resistant resin substrate. The photoresist may be positive-type or negative-type.

2) Exposure is carried out through a photomask of the wiring pattern (a positive-type pattern or a negative-type pattern).

3) The exposed photoresist is developed with a specialized developing liquid. If needed, it is washed with water and dried. In each case using positive-type or negative-type, the photoresist having a shape of the wiring pattern is formed.

4) The bare site of the metal foil is removed with an etching solution etc, and it is washed with water and dried if needed.

5) The photoresist on the metal foil is removed by stripping etc, and it is washed with water and dried if needed.

Throughout the steps above, the metal wiring is formed on the heat resistant resin substrate,

Formation method 2 of a wiring pattern:

The above-described formation method 1 of a wiring pattern is more specifically exemplified for the embodiment using copper foil as the metal foil and using polyimide film as the heat resistant resin substrate, as an example of a series of the production processes from the production of the metal laminated heat resistant resin substrate.

1) The copper foil as the metal foil and the heat resistant resin substrate in which the thermocompression-bondable polyimide layer is laminated on at least one side of high-heat resistant polyimide layer are provided. The copper foil laminated polyimide is produced using a laminate roll capable of heating and pressing the thermocompression-bondable polyimide layer and the surface-treated face of the copper foil, or a press capable of heating and pressing such as a double-belt press.

2) Photoresist layer is formed by applying or affixing a film on the copper foil surface of the copper foil laminate polyimide.

3) Exposure is carried out through a photomask of the wiring pattern.

4) The unexposed site of the photoresist is developed and removed with a specialized developing liquid, and it is washed with water and dried if needed, and the photoresist layer exposed to the wiring pattern is formed on the copper foil.

5) The bare copper is removed with a copper etching solution such as ferric chloride-based, copper chloride-based, hydrogen peroxide-based, and it is washed with water and dried if needed.

6) The exposed photoresist layer on the copper wiring is stripped and removed with a specialized stripping liquid, and it is washed with water and dried if needed.

Throughout the steps above, the copper wiring polyimide can be produced. Although the case using the negative-type photoresist is explained in the above explanation, the positive-type photoresist may also be used.

Formation method 3 of a wiring pattern:

Laser may be used for etching as followings.

1) For example, the metal laminated heat resistant resin substrate used in the above-described formation method 3 of a wiring pattern is prepared.

2) Laser light is irradiated to the metal on the site that will not become the wiring and remove the metal. The remaining metal foil forms the wiring. This method may be used.

Formation method 4 of a wiring pattern;

An example of producing the copper wiring polyimide film through the subtractive method using the copper foil laminated polyimide film is shown,

1) Copper-plating is carried out on the copper foil if needed.

2) Photoresist layer is formed on the upper face of the copper foil.

3) The wiring pattern is exposed through a photomask etc.

4) The site of the photoresist layer other than that to be intended to be the wiring pattern is removed by developing.

5) The site of the copper foil other than that to be intended to be the wiring pattern is removed by etching.

6) The photoresist layer on the copper foil is removed by stripping etc.

In each step of the above-described 1) to 6), washing and drying may be carried out if needed.

Formation method 5 of a wiring pattern:

An example of producing the copper wiring polyimide film through the semi-additive method using the copper foil laminated polyimide film is shown.

1) The copper foil is thinned by etching the copper foil if needed.

2) Photoresist layer is formed on the upper face of the copper foil.

3) The wiring pattern is exposed through a photomask etc.

4) The site of the photoresist layer where the wiring pattern is to be made is developed and removed.

5) The bare site of the copper foil is copper-plated.

6) The photoresist layer on the copper foil is removed by stripping etc.

7) The copper foil on which the photoresist is removed is removed by flash-etching etc to bare the polyimide.

In each step of the above-described 1) to 7), washing and drying is done if needed.

In the formation of the above-described wiring pattern, the photoresist may be either positive-type or negative-type; they may be appropriately selected depending on the production process.

As the etching solution of the metal foil, a well-known etching solution may be used. Examples thereof include potassium ferricyanide aqueous solution, ferric chloride aqueous solution, copper chloride aqueous solution, ammonium persulfate aqueous solution, sodium persulfate aqueous solution, hydrogen peroxide solution, hydrofluoric aqueous solution and combinations of these.

In the present invention, after the metal wiring is formed on the heat resistant resin substrate as above, at least the heat resistant resin substrate surface bared to the surface is washed with the etching solution capable of removing the surface-treatment metal to increase adhesiveness of the resin substrate surface. Here, the surface-treatment metal used for the surface-treatment of the metal foil is usually selected from at least one metal selected from Ni, Cr, Co, Zn, Sn and Mo or an alloy comprising at least one of these metals.

The etching solution capable of removing the surface-treatment metal is not particularly limited as long as it is able to remove the surface-treatment metal at a faster rate than that for the predominant metal component of the metal foil (i.e., the metal wiring). When the metal foil is copper, the etching solution for washing the surface-treatment metal, for example, may be an acidic etching solution containing hydrochloric acid, an alkali etching solution containing potassium ferricyanide or permanganate and the like.

As the etching solution for washing, as long as the etching solution is able to remove mainly the surface-treatment metal, well-known etching solution may be used, such as Ni etching solution, Cr etching solution, Co etching solution, Zn etching solution, Sn etching solution, Mo etching solution, Ni—Cr etching solution, and an acidic etching solution. Among these known etching solutions, it is preferable to select and use those having an etching rate faster than that for the predominant metal component of the metal foil. At the same time, an etching solution giving no damage to the heat resistant resin substrate surface is preferable. This is because if etching reaches into the substrate surface, the effects of the treatment of the resin substrate surface such as polyimide or the metal wiring surface with the silane coupling agent, the treatment for introducing polar groups and the like may be lost.

The metal wiring substrate washed during the washing step of the present invention shows improved adhesiveness of ACF including epoxy resin and the like on the substrate surface. In addition, when at least a part of the metal wiring is plated such as tin-plating, anomalous deposition of the plating metal is inhibited on the bare substrate surface between wirings, and thus, a side benefit is obtained so that electrical insulating property is improved.

For the specific etching solution, if for example, the surface-treatment metal is Ni, Cr or Ni—Cr alloy etc, a known etching agent for Ni—Cr alloy (the Ni—Cr seed layer remover) may be used, for example, well-known etching solution such as MELSTRIP NC-3901 made by Meltex, ADEKA REMOVER NR-135 made by Asahi Denka Kogyo and FLICKER-MH made by Nihon Kagaku Sangyo.

A specific washing condition to remove predominantly the surface-treatment metals may be appropriately selected depending on the etching solution used, and at a temperature of preferably 30 to 60° C., further 40 to 60° C., preferably for 0.3 to 20 min., more preferably 0.5 to 10 min., particularly preferably 1 to 7 min. by a treatment of immersion (dipping) or spraying.

Although the effects of the present invention are evaluated by the adhesion strength, it can be also evaluated by means of measuring an amount of traces of the surface-treatment metal remaining on the substrate surface by elemental analysis of the substrate surface, and an amount of Si existing on the surface. First, for the effects of the present invention, the metal removal efficiency before washing and after washing with the etching solution (after washing/before washing×100) is preferably within a range selected from the following 1) to 4), particularly the Cr removal efficiency is preferably within the following ranges.

1) The Cr removal efficiency is preferably 15% to 100%, 20% to 100%, 25% to 100%, 30% to 100%, 40% to 100%, 50% to 100%.

2) The Co removal efficiency is preferably 20% to 100%, 30% to 100%, 40% to 100%, 50% to 100%, 60% to 100%, 70% to 100%, 80% to 100%.

3) The Zn removal efficiency is preferably 20% to 100%, 30% to 100%, 40% to 100%, 50% to 100%, 60% to 100%, 70% to 100%, 80% to 1.00%.

4) The Mo removal efficiency is preferably 20% to 100%, 30% to 100%, 40% to 100%, 50% to 100%, 60% to 100%, 70% to 100%, 80% to 100%.

The elemental analysis on the surface of the heat resistant resin substrate emerged after removing the metal on the metal wiring heat resistant resin substrate is carried out by using Quantum-2000 scanning X-ray photoelectronic spectrometer made by PHI, and the measurement condition is X-ray source: AlKa (monochrome), analysis area: 100 μm-diameter, use of electron neutralization gun.

In addition, the Cr atomic concentration after washing with the etching solution capable of removing mainly surface-treatment metal is preferably 7.5 atomic % or lower, furthermore 7 atomic % or lower, further 6.5 atomic % or lower.

Furthermore, for the effects of the present invention, the atomic concentration of Si existing on the substrate surface preferably increases after washing with the etching solution. This means that after removing the traces of the treatment metal from the surface, the Si atom from the silane coupling agent used for the surface-treatment of the heat resistant resin substrate or the metal foil emerged just vicinity of the surface. At the same time, this means that the Si atom is not lost due to exceeding etching.

In the production process according to the present invention, for the metal wiring substrate, at least a part of the metal wiring is furthermore metal-plated after completion of the washing step in this manner. As an example for the metal-plating of the metal wiring substrate after washing with the etching solution, in the case of copper wiring, the plated metal wiring substrate may be produced by tin-plating, gold-plating and silver-plating and so on of the copper wiring.

The metal-wiring substrate produced in accordance with the present invention may be utilized as flexible wiring circuit substrates, built-up circuit substrates, or IC carrier tape substrates in the field of every electronics such as computers, terminal machineries, telephones, communications equipments, measurement control machineries, cameras, clocks, cars, office appliances, household electrical appliances, airplane instruments, medical equipments.

### EXAMPLES

The present invention will be more specifically described with reference to the following Examples. However, the present invention is not limited to these Examples.

Physical property evaluation was carried out in accordance with the methods below.

1) Glass transition temperature (Tg) of polyimide film: determined from a peak tan δ value by a dynamic viscoelasticity method (tensile method; frequency: 6.28 rad/sec; temperature rising rate: 10° C./min),

2) Linear expansion coefficient (50 to 200° C.) of polyimide film: an average linear expansion coefficient at 20 to 200° C. is determined by a TUA method (tensile method; temperature rising rate: 5° C./min).

3) Peel strength of metal foil laminated polyimide film (as made), peel strength of polyimide film and adhesion tape: in accordance with JIS-C6471, a lead with 3 mm in width defined in the same test method was made, and for nine test pieces from metal of roll inner side and roll outer side, the 90° peel strength was measured at crosshead speed of 50 mm/min. For the polyimide film and the copper foil laminated polyimide film, its peel strength is an average of nine values. For the laminate of the polyimide film and the adhesive sheet, its peel strength is an average of three values. If the thickness of the metal foil is less than 5 μm, it is electroplated by 20 μm of thickness, and the measurement is carried out. (Roll inner means peel strength of inside of the metal foil laminated polyimide film rewound, and roll outer means peel strength of outside of the metal foil laminated polyimide film rewound.)

4) Peel strength of metal foil laminated polyimide film (after heating at 150° C. and for 168 hours): in accordance with JIS-C6471, a lead with 3 mm in width defined in the same test method was made, and after placing three test pieces in an air circulation thermostatic oven at 150° C. and for 168 hours, the 90° peel strength was measured at crosshead speed of 50 mm/min. The peel strength was an average of three values. If the thickness of the metal foil is less than 5 μm, it is electroplated by 20 μm of thickness, and the measurement is carried out.

The retention rate of peel strength after heating treatment at 150° C. and for 168 hours was calculated in accordance with the numerical formula (1) below. (Roll inner means peel strength of inside of the metal foil laminated polyimide film rewound, and roll outer means peel strength of outside of the metal foil laminated polyimide film rewound.)

X(%)=Z/Y×100

(X is the retention rate of peel strength after heating treatment at 150° C. and for 168 hours, Y is the peel strength before heating, and Z is the peel strength after heating treatment at 150° C. and for 168 hours.)

5) Insulation breakdown voltage of polyimide film: determined in accordance with ASTM-D 149 (the voltage when insulation broke down was measured by increasing voltage at a rate of 1000V/sec). It was measured in air when the thickness of polyimide was up to 50 μm, and measured in oil when the thickness was 50 μm or thicker.

6) Inter wiring insulation resistance, volume resistance of metal foil laminated polyimide film: determined in accordance with JIS-C6471.

7) Mechanical properties of polyimide film
Tensile strength: determined in accordance with ASTM-D882 (cross head speed: 50 mm/min).
Elongation percentage: determined in accordance with ASTM-D882 (cross-head speed: 50 mm/min).
Tensile modulus: determined in accordance with ASTM-D882 (cross-head speed: 5 mm/min).

### Reference Example 1

### Production of Polyimide S1

In N-methyl-2-pyrrolidone, para-phenylenediamine (PPD) and 3,3′,4,4′-biphenyltetracarboxylic dianhydride (s-BPDA) were added in a molar ratio of 1000:998 such that a monomer concentration was 18% (weight %, the same hereinafter), and then the mixture was reacted at 50° C. for 3 hours. The obtained poly(amic acid) solution had a solution viscosity of about 1680 poises at 25° C.

### Reference Example 2

### Production of Polyimide S2

In N-methyl-2-pyrrolidone, 1,3-bis(4-aminophenoxy) benzene (TPE-R) and 2,3,3′,4′-biplienyltetracarboxylic dianhydride (a-BPDA) and 3,3′,4,4′-biphenyltetracarboxylic dianhydride (s-BPDA) were added in a molar ratio of 1000:200:800 such that a monomer concentration was 18%, and further was added triphenyl phosphate in 0.5% by weight relative to the monomers, and then the mixture was reacted at 40° C. for 3 hours. The obtained poly(amic acid) solution had a solution viscosity of about 1680 poises at 25° C.

### Reference Example 3

### Production of Polyimide Film A1

The poly(amic acid) solutions obtained from the reference examples 1 and 2 were flow-casted on a metal support by using a film-forming equipment provided with a three-layer extrusion die (multi-manifold type die) while varying a thickness of the three-layer extrusion die, and after continuously drying under hot air at 140° C., by peeling the self-support film was formed. After peeling this self-support film from the support, solvent was removed by gradually heating from 150° C. to 450° C. in a heating furnace, and imidization was carried out, and the resulting long three-layer polyimide film was wound onto a roll.

Properties of the three-layer polyimide film (S2/S1/S2) obtained were evaluated.
Thickness pattern: 4 μm/17 μm/4 μm (total 25 μm)
Glass transition temperature of the S2 layer: 240° C.
Glass transition temperature of the S1 layer: 340° C. or higher, definite temperature was not detected.
Linear expansion coefficient (50 to 200° C.): MD 19 ppm/° C., TD 17 ppm/° C.
Mechanical properties
1) Tensile strength: MD, TD 520 MPa
2) Coefficient of extension: MD, TD 100%
3) Tensile modulus: MD, TD 7100 MPa
Electrical properties
1) Breakdown voltage: 7.2 kV
2) Dielectric constant (1 GHz): 3.20
3) Dielectric tangent (1 GHz): 0.0047

### Example 1

The rolled-up electrolytic copper foil (made by Nippon Denkai, USLP-R2, thickness 12 μm, surface-treated with silane coupling agent), the polyimide film A1 (three layer structure of S2/S1/S2) produced from Reference Example 3, which was pre-heated by hot air at 200° C. for 30 sec. in line immediately before a double-belt press, and the rolled-up electrolytic copper foil (made by Nippon Denkai, USLP-R2, thickness 12 μm) were laminated, provided to a heating zone (the highest heating temperature: 330° C.) and then provided to a cooling zone (the lowest cooling temperature: 180° C.). Thus, the lamination was completed successively thermocompression-bonding and cooling with a compression-bonding pressure: 3.9 MPa and a compression-bonding time: 2 min, which was then wound around a wind-up roll to form rolled-up polyimide film (width: 540 mm, length: 1000 m), in which carrier-accompanied copper foil has been laminated on both side.

Properties of the rolled-up-form both sides copper foil copper-clad polyimide film obtained were evaluated.
Thickness pattern (copper foil/polyimide/copper foil): 12 μm/25 μm/12 μm
Peel strength (as made): roll inner 1.5 N/mm, roll outer 2.1 N/mm
Peel strength (after heating at 150° C. and for 168 hours): roll inner 1.6 N/mm (retention rate of peel strength 107%), roll outer 2.1 N/mm (retention rate of peel strength 100%)
Solder heat resistance: no abnormality detected.
Dimensional change ratio: (MD direction: −0.03%, TD direction: 0.00%).
Breakdown voltage: 12.0 kV.
Line insulation resistance: 3.3×10¹³Ω·cm.
Volume resistance: 3.6×10¹³Ω·cm.

Washing with Ni—Cr Seed Layer Remover

From the rolled-up-form both sides copper foil laminated polyimide film, a sample of 10 cm×10 cm in size was cut out, and the sample cut-out was dipped into ferric chloride solution (room temperature) as the copper-etching solution for 20 min., washed with water after completely etching and removing the copper foil, then dipped into FLICKER-MH (made by Nihon Kagaku Sangyo Corporation) (temperature 30° C.) solution as the Ni—Cr seed layer remover for 20 min., washed with water, further dipped into 5 wt % NaOH aqueous solution (temperature: 50° C.) for 1 min., and dipped into 3 vol % hydrochloric acid aqueous solution (room temperature: about 20° C.) for 30 sec, and the polyimide film in which copper was etched and removed was obtained.

Production of Adhesion Sheet

25 g of Epicoat 1009 (made by Japan Epoxy Resin) was dissolved in 25 g of mixture solvent of toluene/methyl ethyl ketone (1 part by volume/1 part by volume), and 25 g of latent curing agent HX3942HP (made by Asahi Chemical Industry) and 0.5 g of silane coupling agent KBM-403 (Shinetsu Chemical Industry) were added to give a source dope. The produced dope was applied on a mold-releasing sheet, and dried at 80° C. for 5 min, to give an epoxy-based bonding sheet (thickness: about 30 μm).

Evaluation of Adhesion

The polyimide film on which copper was etched and removed and which was washed with the Ni—Cr seed layer remover and the epoxy-based bonding sheet were directly piled. Using a heat press (MP-WNH made by TOYO SEIKI) under a condition of temperature 170° C. and pressure 30 kgf/cm², they were compressed for 5 min. to give a laminate sheet. For two samples, the obtained laminate sheet and this laminate sheet after hygrothermal treatment (temperature: 105° C., humidity: 100% RH, treatment time: 12 hours), the 90° peel strength was measured, and Table 1 shows the results.

### Example 2

The rolled-up-form both sides copper foil copper-clad polyimide film was produced in a manner similar to Example 1 except that the rolled-up electrolytic copper foil (made by Nippon Denkai, HILS, thickness 9 μm, surface-treated with silane coupling agent) was used as the copper foil Similar to Example 1, “Washing with Ni—Cr seed layer remover,” “Production of adhesion sheet” and “Evaluation of adhesion” was carried out. The results of the 90° peel is shown in Table 1.

### Example 3

The rolled-up-form both sides copper foil copper-clad polyimide film was produced in a manner similar to Example 1 except that the rolled-up electrolytic copper foil (made by Furukawa Circuit Film, F2-WS, thickness 12 μm, surface-treated with silane coupling agent) was used as the copper foil. Similar to Example 1, “Washing with Ni—Cr seed layer remover,” “Production of adhesion sheet” and “Evaluation of adhesion” was carried out. The results of the 90° peel is shown in Table 1.

### Comparative Example 1

Except that polyimide film, after the copper was etched and removed, was not washed with the Ni—Cr seed layer remover in Example 1, in a manner similar to Example 1, the rolled-up-form both sides copper foil copper-clad polyimide film was produced, the copper-etched and -removed polyimide film was produced, the adhesion sheet was produced, and the adhesion was evaluated. The results of the 90° peel is shown in Table 1.

### Comparative Example 2

Except that polyimide film, after the copper was etched and removed, was not washed with the Ni—Cr seed layer remover in Example 2, in a manner similar to Example 1, the rolled-up-form both sides copper foil copper-clad polyimide film was produced, the copper-etched and -removed polyimide film was produced, the adhesion sheet was produced, and the adhesion was evaluated. The results of the 90° peel is shown in Table 1.

### Comparative Example 3

Except that polyimide film, after the copper was etched and removed, was not washed with the Ni—Cr seed layer remover in Example 3, in a manner similar to Example 1, the rolled-up-form both sides copper foil copper-clad polyimide film was produced, the copper-etched and -removed polyimide film was produced, the adhesion sheet was produced, and the adhesion was evaluated. The results of the 90° peel is shown in Table 1.

The elemental analysis on the surface of the polyimide film on which the copper was etched and removed in Example 1, Example 2, Comparative Example 1 and Comparative Example 2 was carried out by using a scanning X-ray photoelectronic spectrometer, and Table 2 shows the measurement results.

The elemental analysis on the surface of the polyimide film used Quantum-2000 made by PHI, a scanning X-ray photoelectronic spectrometer, and the measurement condition is X-ray source: AlKa (monochrome), analysis area: 100 μm-diameter, use of electron neutralization gun.

By comparing the atomic concentration (atomic %) of the polyimide film surface,

1) in Example 1, Example 2, Comparative Example 1 and Comparative Example 2, the atomic concentrations of chrome, cobalt, zinc and molybdenum decreased in Example 1 and Example 2.

2) In all of Example 1, Example 2, Comparative Example 1 and Comparative Example 2, silicon atoms are present, and it is presumed that the silane coupling agent is present on the surface of the polyimide. In addition, for the Si atomic concentrations before and after washing with the etching solution, the concentration increases after washing compared to the concentration before washing.

TABLE 1

| | | Washing | 90° Peel strength (N/mm) | |
|---|---|---|---|---|
| | | with Ni—Cr | | After |
| | | seed layer | | hygrothermal |
| | Copper foil | remover | Initial | treatment |
| Example 1 | USLP-R2 | carried out | 1.06 | 0.32 |
| Comparative | | not carried | 0.50 | 0.08 |
| Example 1 | | out | | |
| Example 2 | HLS | carried out | 0.77 | 0.34 |
| Comparative | | not carried | 0.30 | 0.08 |
| Example 2 | | out | | |
| Example 3 | F2-WS | carried out | 0.93 | 0.51 |
| Comparative | | not carried | 0.64 | 0.37 |
| Example 3 | | out | | |

TABLE 2

| | ESCA analysis result | | | | |
|---|---|---|---|---|---|
| | Si | Cr | Co | Zn | Mo |
| Example 1 | 1.95 | 6.22 | Below | Below | Below |
| | | | detection | detection | detection |
| | | | limit | limit | limit |
| Comparative | 1.58 | 9.09 | 1.32 | 0.42 | 0.22 |
| Example 1 | | | | | |
| Example 2 | 5.4 | 4.8 | Below | Below | 0.05 |
| | | | detection | detection | |
| | | | limit | limit | |
| Comparative | 3.9 | 10.5 | 0.81 | 0.11 | 0.3 |
| Example 2 | | | | | |

### Example 4

The rolled-up electrolytic copper foil (made by Nippon Denkai, HLS, thickness 9 μm, surface-treated with silane coupling agent), the polyimide film S1 (three layer structure of S2/S1/S2) produced from Reference Example 3, which was pre-heated by hot air at 200° C. for 30 sec. in line immediately before a double-belt press, and Upilex S (made by Ube Industries, thickness 25 μm) were laminated, provided to a heating zone (the highest heating temperature: 330° C.) and then provided to a cooling zone (the lowest cooling temperature: 180° C.). Thus, the lamination was completed successively thermocompression-bonding and cooling with a compression-bonding pressure: 3.9 MPa and a compression-bonding time: 2 min, which was then wound around a wind-up roll to form rolled-up polyimide film (width: 540 mm, length: 1000 m), in which carrier-accompanied copper foil has been laminated on one side.

The rolled-up-form one side copper foil copper-clad polyimide film was cut out, and after laminating the dry film-type negative-type photoresist (UFG-072 made by Asahi Chemical Industry) on the copper foil of the copper-clad polyimide film by a heat roll at 110° C., a site where circuit is intended to be formed was exposed, and unexposed resist was spray-developed with 1% sodium carbonate aqueous solution and removed at 30° C. for 20 sec., and the bare site of the copper foil was spray-etched with ferric chloride solution at 50° C. for 15 sec to form copper wiring with 44 μm in pitch. Subsequently, the resist was stripped by spray-treatment with 2% sodium hydroxide aqueous solution at 42° C. for 15 sec. The copper wiring polyimide film was dipping into FLICKER-MH made by Nihon Kagaku Sangyo as Ni—Cr seed layer remover at 45° C. for 5 min., the copper circuit site was tin-plated using Tinpogit LT-34H made by SHIPLEY at 80° C. for 4 min.

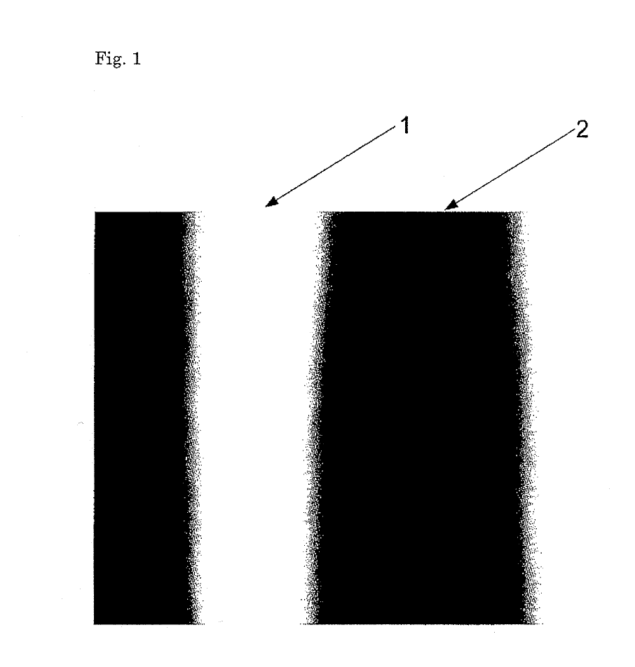

With respect to the tin-plated copper wiring and the polyimide film surface where the copper foil was removed between copper wirings of the tin-plated copper-wiring polyimide film, an image of a metallographic microscope (lens magnification: 1,000 times, reflected light) was obtained, which is shown in FIG. 1. From FIG. 1, the polyimide surface where the copper foil was removed was clean, and no occurrence of anomalous metal deposition by tin-plating at the junction site of (i.e. border of the copper wiring and polyimide where the copper foil was removed between copper wirings or on the polyimide surface where the copper foil was removed between copper wirings was detected.

### Comparative Example 4

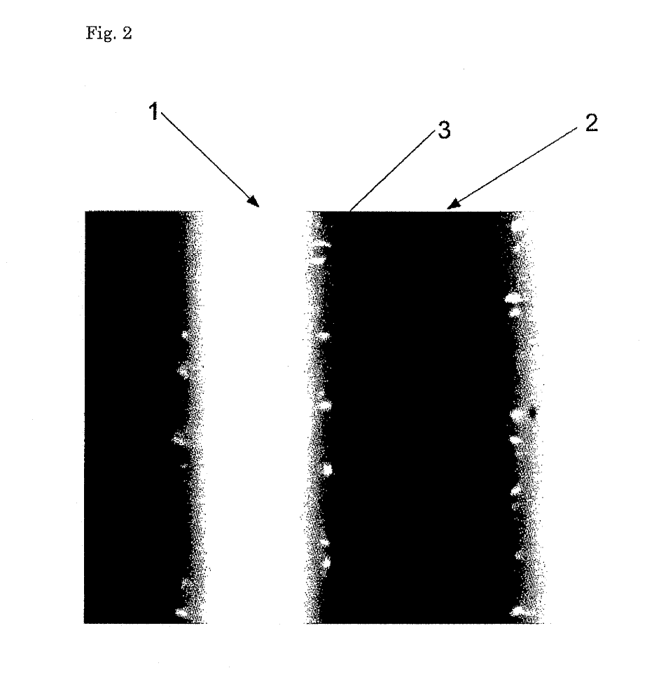

Using the rolled-up-form one side copper foil copper-clad polyimide film produced from Example 4, the copper-clad polyimide film was cut out, and after laminating the dry film-type negative-type photoresist (UFG-072 made by Asahi Chemical Industry) on the copper-clad polyimide film by a heat roll at 110° C., a site where circuit is intended to be formed was exposed, and unexposed resist was spray-developed with 1% sodium carbonate aqueous solution and removed at 30° C. for 20 sec., and the bare site of the copper foil was spray-etched with ferric chloride solution at 50° C. for 15 sec to form copper wiring with 44 μm in pitch. Subsequently, the resist was stripped by spray-treatment with 2% sodium hydroxide aqueous solution at 42° C. for 15 sec., and the copper circuit site was tin-plated using Tinpogit LT-34H made by SHIPLEY at 80° C. for 4 min. With respect to the obtained tin-plated copper wiring polyimide film, an image of a metallographic microscope was obtained in a similar manner to Example 4, which is shown in FIG. 2.

From FIG. 2, lots of occurrence of anomalous metal deposition by tin-plating at the junction site of the copper wiring and polyimide where the copper foil was removed between copper wirings and on the polyimide film surface where the copper foil was removed between copper wirings were detected.

1. A process for producing a metal wiring substrate comprising a heat resistant resin substrate and a metal wiring which is laminated on the substrate and in which a surface laminated with the substrate is surface-treated with at least one metal selected from Ni, Cr, Co, Zn, Sn and Mo or an alloy comprising at least one of these metals (hereafter, the metal used for the surface-treatment is referred to as a surface-treatment metal), comprising the steps of:
forming the metal wiring on the resin substrate, and
washing at least a surface of the resin substrate with an etching solution capable of removing the surface-treatment metal to increase adhesion of the surface of the resin substrate.

2. The production process according to claim 1, wherein the metal wiring substrate is used for an application in which an adhesive organic material layer is formed on at least a part of a bare face of the resin substrate on which the metal wiring is formed.

3. The production process according to claim 2, wherein the adhesive organic material layer is a layer having at least one function selected from a conductive layer, an insulating layer, a protective layer, an adhesion layer, an encapsulating layer and a sealing layer.

4. The production process according to claim 1, wherein the etching solution is capable of removing the surface-treatment metal at a faster rate than a rate for a material of the metal wiring.

5. The production process according to claim 1, wherein at least one of a surface of the resin substrate and a surface of the metal wiring is treated with a silane coupling agent at a laminating face of the resin substrate and the metal wiring, and
wherein the washing step is carried out so that a surface silicon atomic concentration after the treatment becomes a higher than that before the treatment.

6. The production process according to claim 1, wherein the resin substrate is one in which a thermocompression-bondable polyimide layer is laminated on at least one side of a heat resistant polyimide layer, and the thermocompression-bondable polyimide layer is the laminating face with the metal wiring.

7. The production process according to claim 1, wherein the etching solution is an acidic etching solution.

8. The production process according to claim 1, wherein the etching solution is an etching agent for a Ni—Cr alloy.

9. The production process according to claim 1, wherein the step for forming the metal wiring, comprising the steps of:
preparing a laminate substrate in which a metal foil is laminated on at least one side of the resin substrate, and
forming the metal wiring on the resin substrate by etching and pattering the metal foil.

10. The production process according to claim 1, wherein the metal wiring is copper wiring.

11. The production process according to claim 1, further comprising a step of plating a metal after the washing step.

12. The metal wiring substrate produced by the production process according to claim 1, comprising the heat resistant resin substrate and the metal wiring which is laminated on the substrate and in which the surface laminated with the substrate is surface-treated with at least one metal selected from Ni, Cr, Co, Zn, Sn and Mo or an alloy comprising at least one of these metals (hereafter, the metal used for the surface treatment is referred to as a surface-treatment metal).

13. The metal wiring substrate according to claim 12, wherein the adhesive organic material layer is formed contacting the resin substrate face of the metal wiring substrate.

14. The metal wiring substrate according to claim 13, wherein the adhesive organic material layer is a layer having at least one function selected from the protective layer, the adhesive layer, the encapsulating layer and the sealing layer.
